(19) United States
(12) Patent Application Publication
(10) Pub. No.: US 2007/0139054 A1
(43) Pub. Date: Jun. 21, 2007

(54) Stimulation-response measurement system and method using a chaotic lock-in amplifier

(76) Inventors: Nicholas B. Tufillaro, Corvallis, OR (US); Gregory D. VanWiggeren, San Jose, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/314,791

(22) Filed: Dec. 21, 2005

(51) Int. Cl. G01R 31/08

(52) U.S. Cl. 324/527

(57) ABSTRACT

A measurement system, a chaotic lock-in amplifier, and methods use chaotic lock-in amplification to measure a stimulus response from one or more of a device under test, a sample under test and a system under test. The measurement system includes a chaotic reference source, a chaotic excitation source and a chaotic lock-in amplifier to facilitate detection of a chaotic response signal from the respective item(s) under test. A chaotic lock-in amplifier includes an inverse system that removes a chaotic component from the chaotic response signal. A method of measuring a response to a stimulation includes using the chaotic reference signal to achieve chaotic lock-in amplification that preferentially removes a chaotic component from the chaotic response signal.

### CROSS-REFERENCE TO RELATED APPLICATIONS

N/A

### STATEMENT REGARDING FEDERALLY SPONSORED RESEARCH OR DEVELOPMENT

N/A

### BACKGROUND

A stimulation-response measurement system performs measurements on a sample (SUT), system (SUT), or device under test (DUT) by applying a stimulation signal to the SUT or DUT and observing or detecting a response to that applied stimulation. In many such stimulation-response measurement systems, a lock-in amplifier is employed to detect and extract a response signal that is buried in or otherwise obscured by noise. In particular, the lock-in amplifier locks onto the response signal thereby improving a signal to noise ratio thereof.

In conventional stimulation-response measurement systems that employ lock-in amplifiers, a periodic reference signal is employed to modulate or vary the stimulation signal. The periodic modulation of the stimulation signal is reflected in the response signal as a periodic modulation of the response. The lock-in amplifier multiplies the response signal by either the periodic reference signal itself or a synchronized replica thereof. The multiplication produces a product having a baseband component and a high frequency component. A lowpass filter is then used to selectively reject the high frequency component and recover a response of the SUT to the stimulation contained in the baseband component of the product. In addition to recovering the SUT or DUT response, the lock-in amplifier also selectively removes or reduces noise components present in the response signal producing an overall improvement in a signal to noise ratio (SNR) of the response after lock-in processing. Measuring features of the baseband component facilitates characterizing a performance of the SUT to the stimulation. In general, the SNR improvement afforded by the lock-in processing enables measuring to produce a higher quality characterization of the SUT than would have been produced if the measuring had been performed directly on the response signal from the SUT.

Unfortunately, conventional stimulation-response measurement systems are inherently narrowband. In particular, the modulation of the stimulation signal has but a single frequency. As such, to measure a response of the SUT or DUT to a range of stimulation frequencies, a frequency sweep of the periodic reference signal must be performed. Essentially, the stimulation-response measurement must be performed multiple times at different modulation frequencies to test the SUT or DUT when a broadband stimulation-response is desired.

### BRIEF SUMMARY

In some embodiments of the present invention, a stimulus-response measurement system employing a chaotic lock-in amplifier is provided. The stimulus-response measurement system comprises a chaotic reference source that produces a chaotic reference signal. The stimulus-response measurement system further comprises a chaotic excitation source and a chaotic lock-in amplifier. The chaotic excitation source produces a chaotic excitation signal from the chaotic reference signal. The chaotic lock-in amplifier employs the chaotic reference signal to lock-in a chaotic component of a chaotic response signal produced by a device under test. The device under test is stimulated by the chaotic excitation signal, such that the lock-in facilitates detection of the chaotic response signal.

In other embodiments of the present invention, a chaotic lock-in amplifier is provided. The chaotic lock-in amplifier comprises a multiplier that receives a chaotic input signal at a first input port. The chaotic lock-in amplifier further comprises a chaotic reference source that generates a chaotic reference signal. The chaotic reference signal is applied to a second input port of the multiplier. The multiplier multiplies together the chaotic input signal and the chaotic reference signal to produce a product thereof.

In other embodiments of the present invention, a quadrature chaotic lock-in amplifier is provided. The quadrature chaotic lock-in amplifier comprises an in-phase channel and a quadrature channel. The in-phase channel comprises a first multiplier having a first input and a second input. The first input is connected to an input port of the quadrature chaotic lock-in amplifier and the second input is connected to a reference port of the quadrature chaotic lock-in amplifier. The quadrature channel comprises a second multiplier having a first input and a second input. The first input of the second multiplier is connected to the input port of the quadrature chaotic lock-in amplifier. The quadrature lock-in amplifier further comprises a quadrature phase shifter having an input connected to the reference port of the quadrature chaotic lock-in amplifier and an output connected to the second input of the second multiplier. In the quadrature chaotic lock-in amplifier, a chaotic reference signal applied to the reference port is phase-shifted by essentially 90-degrees by the quadrature phase shifter to produce a quadrature chaotic reference. A chaotic input signal introduced to the input port is multiplied by the chaotic reference signal in the first multiplier to produce an in-phase product. The chaotic input signal introduced is also multiplied by the quadrature chaotic reference in the second multiplier of the quadrature channel to produce a quadrature product.

In other embodiments of the present invention, a method of measuring a response to a stimulation using chaotic lock-in amplification is provided. The method of measuring comprises generating a chaotic reference signal and creating a chaotic stimulus signal having at least one signal component that is proportional to the chaotic reference signal. The method of measuring further comprises applying the chaotic stimulus signal to an input of one or more of a sample under test, a device under test, and a system under test to produce a chaotic response signal and achieving chaotic lock-in amplification of the chaotic response signal using the chaotic reference signal. The chaotic lock-in amplification preferentially removes a chaotic component from the response signal to yield a measurement of a response of the respective sample under test, device under test, and system under test to the stimulation.

In yet other embodiments of the present invention, a method of quadrature chaotic lock-in amplification is provided. The method of quadrature chaotic lock-in amplification comprises forming an in-phase chaotic product by multiplying together a chaotic input signal and a chaotic reference signal. The method of quadrature chaotic lock-in amplification further comprises forming a quadrature chaotic product by multiplying together the chaotic input signal and a phase-shifted chaotic reference signal. The phase-shifted chaotic reference signal is the chaotic reference signal having an instantaneous phase shift of approximately 90-degrees.

Certain embodiments of the present invention have other features that are one or both of in addition to and in lieu of the features described above. These and other features of the invention are detailed below with reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1A illustrates a block diagram of a stimulation-response measurement system according to an embodiment of the present invention.

FIG. 1B illustrates a block diagram of a stimulation-response measurement system according to another embodiment of the present invention.

FIG. 1C illustrates a block diagram of a stimulation-response measurement system that employs an inverse system according to an embodiment of the present invention.

FIG. 2A illustrates a block diagram of a chaotic excitation source according to an embodiment of the present invention.

FIG. 2B illustrates a block diagram of a chaotic excitation source according to another embodiment of the present invention.

FIG. 2C illustrates a block diagram of a chaotic excitation source according to another embodiment of the present invention.

FIG. 3 illustrates a block diagram of a chaotic lock-in amplifier employed in the measurement system illustrated in FIGS. 1A-1B according to an embodiment of the present invention.

FIG. 4 illustrates a block diagram of a quadrature chaotic lock-in amplifier according to an embodiment of the present invention.

FIG. 5 illustrates a flow chart of a method of measuring a response to a stimulation using chaotic lock-in amplification according to an embodiment of the present invention.

FIG. 6 illustrates a flow chart of a method of quadrature chaotic lock-in amplification according to an embodiment of the present invention.

### DETAILED DESCRIPTION

The embodiments of the present invention facilitate one or both of detecting and recovering signals in the presence of noise. In some embodiments, the detected signal is a relatively small or low power signal when compared to an average level or power of the noise. Moreover, the detected signal may be a broadband signal having a rich or extended spectral structure. Various embodiments of the present invention are applicable to a diverse range of measurement applications including, but not limited to, electrical systems, mechanical systems, and optical system. Examples of specific measurement applications include, but are not limited to, spectral analysis of stimulated infrared spectra, stimulated fluorescence and phosphorescence, optical absorption, reflection/impedance, and broadband testing of electrical and mechanical systems (e.g., radio frequency (RF) ultra-wideband (UWB) transceivers, micromechanical resonators, etc.).

According to various embodiments of the invention, a chaotic signal is employed as a reference signal in conjunction with a phase sensitive detector (PSD) to realize a chaotic lock-in amplifier. The chaotic lock-in amplifier employs the chaotic reference signal to ‘lock-in’ a chaotic component or portion of an input signal to the chaotic lock-in amplifier. In some embodiments, the chaotic component of the input signal is essentially removed from the input signal to produce an output signal of the chaotic lock-in amplifier. For example, the chaotic component may comprise a carrier component or signal of the input signal. In such embodiments, the chaotic lock-in amplifier essentially removes the chaotic carrier. In another example, the chaotic component comprises a chaotic modulation of the input signal wherein the chaotic lock-in amplifier essentially acts as a demodulator to remove or undo the chaotic modulation.

In general, noise present in the input signal as noise components are uncorrelated with the chaotic component. The lack of correlation may result in a level of the noise components, which is an average level relative to other components of the input signal, being essentially reduced by the action of the chaotic lock-in amplifier. As such, the chaotic lock-in amplifier may be employed to improve or increase an overall signal to noise ratio of an output signal of the chaotic lock-in amplifier compared to the input signal when the input signal comprises a chaotic component (e.g., one or both of a chaotic modulation and a chaotic carrier). The improved signal to noise ratio afforded by the chaotic lock-in amplifier in measurement applications may facilitate detection of the signal (e.g., a response signal) in the presence of relatively high noise levels, for example.

As used herein, the term ‘chaotic signal’ refers to a signal that exhibits chaotic motion or chaotic oscillation. For a signal to exhibit chaotic oscillation, a characteristic of the signal (e.g. one or both of magnitude and phase, as a function of time) generally follows or ‘traces out’ an essentially chaotic trajectory or orbit when plotted or viewed in a state space or as a phase diagram (i.e., the signal exhibits chaotic motion). Specifically, when plotted or represented in state space, a characteristic of the chaotic signal will exhibit or ‘trace out’ a trajectory exemplified by a ‘strange attractor’. The trajectory exemplified by the strange attractor is as opposed to a so-called ‘normal attractor’ associated with a periodic signal, for example. A chaotic signal may be an output of, or produced by, a chaotic system, for example. The chaotic system is defined as a system in which a characteristic or operational mode thereof is governed by, or defined in terms of, chaos theory.

Chaos theory is a branch of both mathematics and physics that deals with certain nonlinear dynamical systems known to exhibit chaos. A principle characteristic of chaos is a high degree of sensitivity to initial conditions. In particular, a fundamental property of chaotic oscillation is an inherent, long-term unpredictability associated with small variations or perturbations in an initial condition of a deterministic system. For example, a deterministic system having an output which diverges rapidly (e.g., exponentially) in essentially differing directions in state space, as a result of small perturbations in the initial conditions of the system, exhibits chaos and is typically termed a ‘chaotic system’. For example, a Lorenz system associated with a so-called Lorenz attractor is a well-known chaotic system that may be employed to generate a chaotic signal. A Lorenz system, defined in terms of coupled differential equations, is described in more detail below. Chaos theory and examples of other chaotic systems and signals are familiar to one skilled in the art as exemplified by N. B. Tufillaro et al., An Experimental Approach to Nonlinear Dynamics and Chaos, Addison-Wesley, 1992, incorporated herein by reference.

Chaos and chaotic outputs may arise in certain types of solutions to a differential equation or a set of differential equations. In particular, when a solution has two orbits or trajectories in state space, such that the two orbits begin close together for close initial conditions and diverge essentially exponentially from one another as time progresses, the solution is typically considered to exhibit chaos, i.e., a chaotic solution.

A classical example of a chaotic system described by such a chaotic solution type is that of a differential equation describing an inverted pendulum started or released at an apex of the pendulum's motion. Small perturbations in an initial condition (e.g., initial or release location) of the inverted pendulum result in a motion of the pendulum away from the apex that is in either a clockwise or a counterclockwise direction about a point of rotation of the pendulum. When plotted in state space, these small perturbations in the initial condition of the pendulum produce two distinctly different and rapidly diverging orbits, one for the clockwise rotation and a second for the counterclockwise rotation.

Another example of a chaotic system is a dynamical system governed or described by the Lorenz system comprising a system of three coupled ordinary differential equations (ODEs) given by equation (1)
\dot{x}=σ(x−y)
\dot{y}=rx−y−xz
\dot{z}=xy−bz (1)
where variables \dot{x}, \dot{y} and \dot{z} are first derivatives with respect to time of variables x, y and z, respectively, and parameters σ, b and r are arbitrary predetermined constants, for example and not by way of limitation, s=10, b=8/3, and r=28).

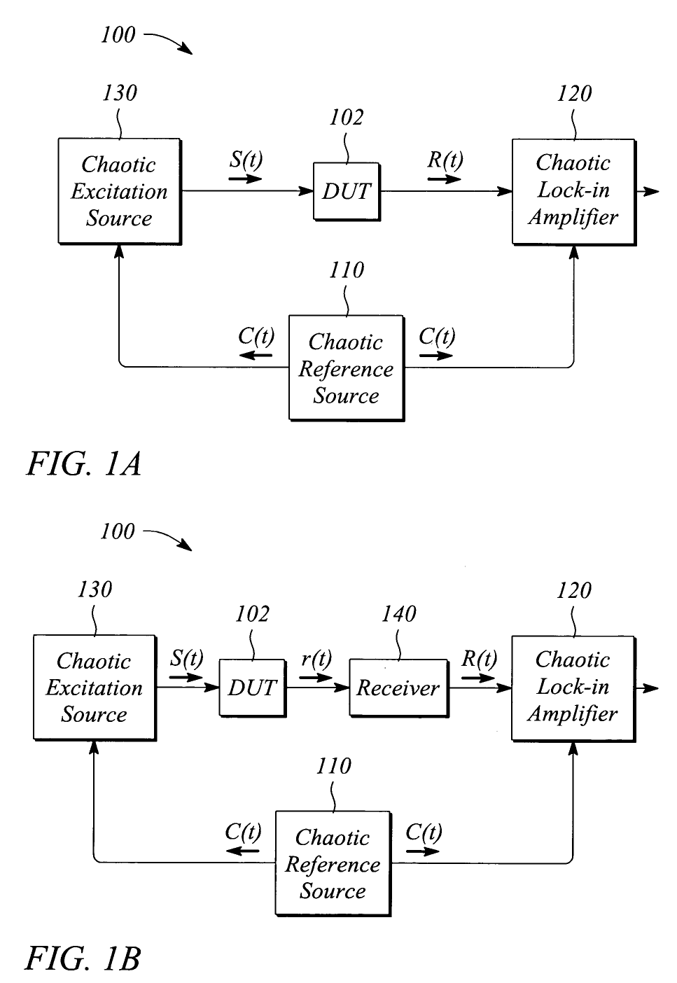

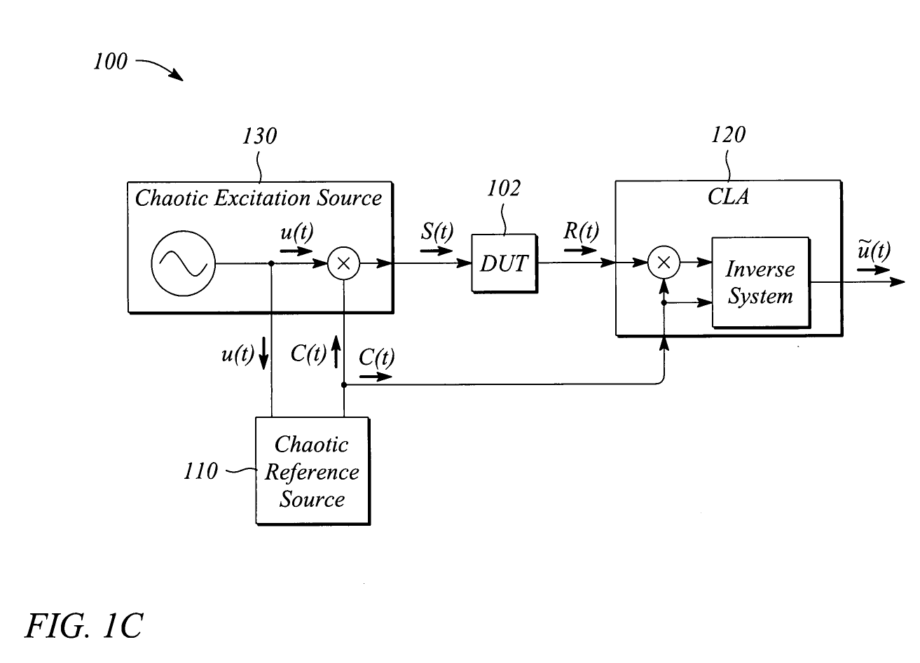

FIG. 1A illustrates a block diagram of a stimulation-response measurement system 100 according to an embodiment of the present invention. FIG. 11B illustrates a block diagram of a stimulation-response measurement system 100 according to another embodiment of the present invention. The measurement system 100 stimulates one or more of a sample, a system and a device under test (DUT) 102. For purposes of discussion and not by way of limitation herein, a ‘DUT 102’ will be understood to represent one or more of the sample, the system and the device under test that is stimulated and measured by the system 100, unless otherwise indicated. A response of the stimulated DUT 102 is detected and measured by the measurement system 100 to characterize the DUT 102. In particular, a chaotic signal component embedded in a stimulation signal applied to the DUT 102 is employed by the measurement system 100 to improve a signal to noise ratio of the measured response in characterizing the DUT 102.

As illustrated in FIG. 1A, the measurement system 100 comprises a chaotic reference source 110. The chaotic reference source 110 produces a chaotic reference signal C(t). Essentially any signal source capable of producing a chaotic signal C(t) may be employed as the chaotic reference source 110. For example, an arbitrary waveform generator appropriately programmed to generate the chaotic reference signal C(t) may be employed as the chaotic reference source 110. In another example, a computer simulation of a chaotic system (e.g., solution to a set of differential equations), an output of which is passed through a digital to analog converter (DAC), may be employed as the chaotic reference source 110. In yet another example, an oscillator modulated by a chaotic system may be employed as the chaotic reference source 110.

The measurement system 100 further comprises a chaotic lock-in amplifier (CLA) 120 having an input port, a reference port and an output port. The chaotic reference source 110 is connected to the reference port of the CLA 120 such that the chaotic reference signal C(t) is communicated to and applied to the CLA 120 reference port. A chaotic response signal R(t), representing the response of the DUT 102, is communicated to and applied to the input port of the CLA 120.

In some embodiments, the CLA 120 produces an output signal that is proportional to a multiplication of, or product of, the chaotic response signal R(t) and the chaotic reference signal C(t). In various embodiments, the product produced by the CLA 120 may be either a real product or a complex product, the complex product having both a real component and an imaginary component. For example, the product may have an in-phase (I) component, and a quadrature (Q) component.

For example, the CLA 120 comprises an analog voltage multiplier such as, but not limited to, a mixer and an analog multiplier (i.e., either real or complex). In another example, the CLA 120 comprises a digital multiplier. In yet other exemplary embodiment, the CLA 120 is implemented as a computer program in either a general purpose computer or a specialized processor. Examples of a specialized processor include, but are not limited to, a discrete logic circuit, a signal processor and an application specific integrated circuit (ASIC).

As such, in some embodiments, the CLA 120 comprises essentially a phase sensitive detector (PSD) having a reference input port capable of accepting and employing the chaotic reference signal C(t) from the chaotic reference source 110. In such embodiments, the CLA 120 may be implemented as an essentially conventional PSD 120 that operates on an input signal (i.e., chaotic response signal R(t)) using the chaotic reference signal C(t) in a manner that is analogous to a conventional PSD-based lock-in amplifier operating on an input signal using a periodic reference signal, as is further described below.

In some embodiments, the CLA 120 further comprises a filter that filters the product of the chaotic response signal R(t) and the chaotic reference signal C(t). In such embodiments, the filter may comprise a lowpass transfer function and is termed a ‘lowpass’ filter. In various embodiments, the filter may be implemented as one or more of an analog filter and a digital filter, depending on a particular realization and application of the CLA 120.

Referring to FIG. 1B, in some embodiments, the measurement system 100 optionally further comprises a receiver 140. As illustrated in FIG. 1B, an input of the receiver 140 is connected to an output of the DUT 102. An output of the receiver is connected to the input port of the chaotic lock-in amplifier 120. The receiver 140 converts a response or output signal r(t) of the DUT 102 into the chaotic response signal R(t). In particular, the receiver 140 is responsible for converting the DUT 102 output signal r(t) into an appropriate form such that the chaotic response signal R(t) is compatible with the chaotic lock-in amplifier 120 input. For example, the DUT 102 output signal r(t) may be an optical signal and the chaotic lock-in amplifier 120 input may be compatible with an analog voltage. In such an exemplary embodiment, the receiver 140 may comprise an optical detector including, but not limited to, a photodiode and a phototransistor, that converts the optical signal into an analog voltage waveform. In another example, the receiver 140 may comprise a radio receiver that downconverts a radio frequency (RF) or microwave signal (i.e., the DUT output signal r(t)) to either an intermediate frequency (IF) or video signal (i.e., the chaotic response signal R(t)) that is compatible with the chaotic lock-in amplifier 120.

FIG. 1C illustrates a block diagram of a stimulation-response measurement system 100 that employs an inverse system according to an embodiment of the present invention. Specifically, as illustrated in FIG. 1C, the CLA 120 comprises an inverse system. As used herein, the ‘inverse system’ is defined as a system that essentially implements a mathematical inverse of a chaotic modulation present in the chaotic response signal R(t). With respect to a chaotic lock-in amplifier, the chaotic modulation is the chaotic component or portion of the chaotic response signal R(t) that is removed by the CLA 120 using the chaotic reference signal C(t). However, embodiments of the CLA 120 that include an inverse system employ specific knowledge of how the chaotic modulation is created in order to undo or remove it from the chaotic response signal R(t). In other words, the inverse system essentially inverts non-transient behavior of a nonlinear dynamical system represented by the chaotic modulation. In particular, the inverse system may be implemented as, or described by, a set or system of inverse demodulator equations that essentially undo or implement an inverse of a set or system of modulator equations. Examples of using inverse functions in chaotic communications system is described by Abel et al., in “Chaos Communications—Principles, Schemes, and System Analysis,” Proc. IEEE, Vol. 90, No. 5, May 2002, pp. 691-710, incorporated herein by reference.

In some embodiments that employ the inverse system, the chaotic reference signal C(t) may essentially transmit or carry an explicit copy of an input signal u(t). In addition, when a difference system is used to generate the chaotic reference signal C(t), the difference system may have a fixed point at an origin to assist in self-synchronization between a signal used to stimulate the DUT 102 and a response signal from the DUT 102. Further, in order to provide relatively robust synchronizations in view of small perturbations, the fixed point may be hyperbolic, in some embodiments. Moreover, in some embodiments, eigenvalues of the fixed point are essentially negative such that transients will decay relatively quickly. Such a chaotic reference signal C(t) may be readily implemented as a simple analog circuit, for example. Examples of circuits that may be employed to generate the chaotic reference signal C(t) for use with the inverse system is presented by J. C. Sprott, “Simple chaotic systems and circuits,” Am. J. Phys., Vol. 68, No. 8, August 2000, pp. 758-763, and by K. Kiers et al., “Precision measurement of a simple chaotic circuit,” Am. J. Phys., Vol. 72, No. 4, April 2004, pp. 503-509, both of which are incorporated by reference herein.

For example, a nonautonomous, three-dimensional oscillator system described in terms of a 3-dimensional state vector x=(x₁(t), x₂(t), x₃(t)) may be employed to generate a suitable chaotic reference signal C(t) by modulator equations (2) below. The modulator equations are given by
x′=Ax+bƒ(x,u)
y=c^{T}x+ƒ(x,u)
ƒ(x,u)=(x₁+DC)²·u(t) (2)
where the vector x′ is a first time derivative of the state vector x, the variable y is an output of the oscillator, the matrix A is constant matrix that defines a linear dynamic differential equation given by x′=Ax, the vector b is a 3-dimensional column vector of predetermined, arbitrarily chosen coefficients (e.g., b=[0,0,1]^{T}), the vector c^{T} is a transpose of another 3-dimensional vector of predetermined, arbitrarily chosen coefficients (e.g., c^{T}=[1,0,0]), and the term DC is a predetermined, arbitrarily chosen, constant offset. A first variable x₁(t) of the vector x is referred to as a modulator. The modulator x₁(t) may be passed through a band-limiting filter so that the variable has a well-defined center frequency. In some embodiments, the well-defined center frequency is much higher than a center frequency of the input signal u(t). In some embodiments, the modulator x₁(t) is essentially equivalent to the chaotic reference signal C(t). The function ƒ(•) may be essentially any function. Explicit reference to time t is suppressed in the modulator equations (2) for notational simplicity and not by way of limitation.

Inverse demodulator equations corresponding to the modulator equations (2) may be given by demodulator equations (3) as
z′=Az+b(y−c^{T}z)
ũ=ƒ⁻¹(z,y−c^{T}z) (3)
where the vector z′ is a first time derivative of the state vector z, and ƒ⁻¹(•) is an inverse of the function ƒ(•) with respect to the input signal u. In equations (3), the term ũ is essentially the input signal u(t) plus any signal characteristics introduced by the action of the DUT 102 on the input signal. As such, ũ (i.e., ũ(t)) represents an output of the measurement system 100 that may be analyzed for information (e.g., spectral analysis, absorption/reflection, etc.) regarding performance of the DUT 102.

In some embodiments, the inverse function ƒ⁻¹(•) is essentially a function that produces a feedback (e.g., a simplest feedback) that will create chaotic motion for parameter regions that are experimentally realizable. For example, if the function ƒ(•) is a quadratic function, the inverse dynamical system and associated inverse function ƒ⁻¹(•) is readily determined using the quadratic formula and keeping track of which root of the quadratic is being employed. In general, the inverse function ƒ⁻¹(•) may be determined either analytically or numerically (e.g., using a root finding algorithm). For example, see M. Sain et al., “Invertibility of Linear Time-Invariant Dynamical Systems,” IEEE Trans. Automatic Control, Vol. 14, No. 2, April 1969, pp. 141-149, incorporated herein by reference.

A difference system applicable to the above-described modulator equations (2) and demodulator equations (3) is described by equations (4) as
d′=A·d−b(c^{T}·d)
d=x−z (4)
The difference system described by equations (4) essentially measures the difference between the input and output signals. Specifically, the difference system state vector d approaches zero as the systems represented respectively by the modulator equations (2) and demodulator equations become synchronized. In some embodiments, the difference system of equation (4) may be employed to determine a degree of lock-in. In some embodiments, a combination (not illustrated) of the chaotic reference source 110 and the CLA 120 is referred to also as a ‘chaotic lock-in amplifier’.

The measurement system 100 illustrated in FIG. 1C further comprises a chaotic excitation source 130 that produces a chaotic stimulus signal S(t) at an output thereof. The chaotic stimulus signal S(t) is synchronized with the chaotic reference signal C(t). In particular, the chaotic excitation source 130 produces the chaotic stimulus signal S(t) comprising a component that is proportional the chaotic reference signal C(t). As such, the chaotic stimulus signal S(t) and the chaotic reference signal C(t) are said to be ‘synchronized’ by virtue of the proportionality therebetween.

The output of the chaotic excitation source 130 is connected to an input of the DUT 102 such that the chaotic stimulus signal S(t) is applied thereto. In some embodiments, the chaotic reference source 110 is connected to the chaotic excitation source 130 such that the chaotic excitation source 130 receives the chaotic reference signal C(t). The received the chaotic reference signal C(t) is employed to facilitate the synchronization.

For example, the chaotic stimulus signal S(t) may comprise a signal that is modulated by the chaotic reference signal C(t). The modulation of the signal may be an amplitude modulation (AM). Essentially any amplitude modulation may be employed including, but not limited to, analog AM, ON/OFF keying (OOK), amplitude shift keying (ASK), pulse width modulation, pulse position modulation, pulse amplitude modulation, and combinations thereof. In another example, the chaotic stimulus signal S(t) may comprise a signal (e.g., baseband signal) that is applied to a chaotic carrier wherein the chaotic carrier is proportional to the chaotic reference signal C(t). In yet another example, the chaotic stimulus signal S(t) may comprise the chaotic carrier that is further modulated in a manner that is proportional to the chaotic reference signal C(t). One skilled in the art may readily devise additional stimulus signals S(t) that have one or more components proportional to the chaotic reference signal C(t) beyond the above-enumerated examples without departing from the scope of the present invention.

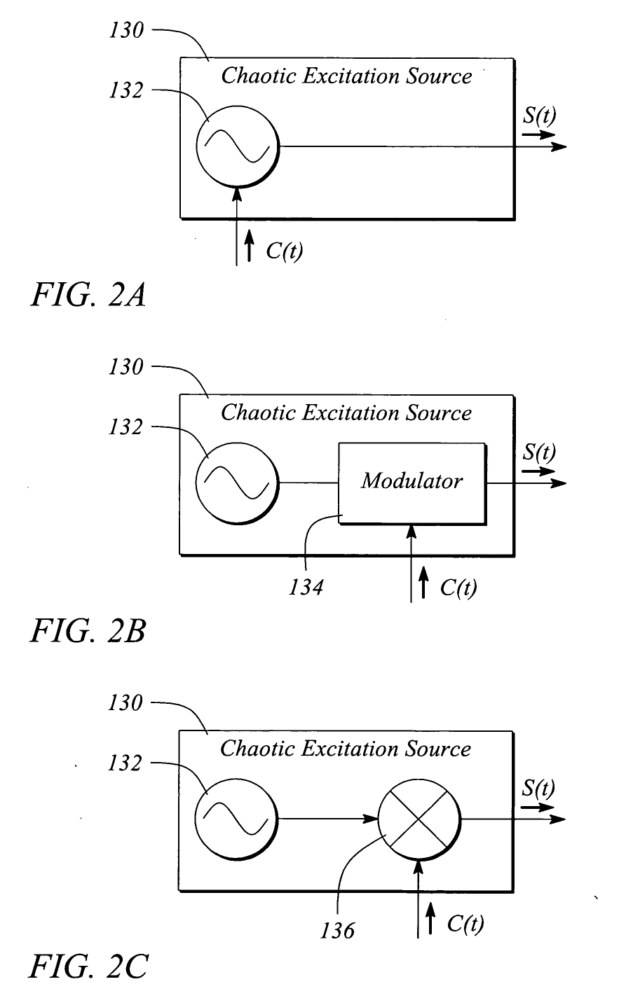

FIG. 2A illustrates a block diagram of a chaotic excitation source 130 according to an embodiment of the present invention. As illustrated in FIG. 2A, the chaotic excitation source 130 comprises a signal source 132 that is a directly modulated or directly varied signal source 132. In various embodiments of the directly varied signal source 132, a characteristic or parameter of an output signal of the signal source 132 is varied by an application of an input or control signal. The directly modulated signal source 132 receives the chaotic reference signal C(t) as the input or control signal and produces an output signal from the signal source 132 having a variation that is proportional to the chaotic reference signal C(t). The varied output signal produced by directly modulated signal source 132 is the chaotic stimulus signal S(t) of the chaotic excitation source 130 illustrated in FIG. 2A.

FIG. 2B illustrates a block diagram of a chaotic excitation source 130 according to another embodiment of the present invention. As illustrated in FIG. 2B, the chaotic excitation source 130 comprises a signal source 132 and a modulator 134. The signal source 132 includes, but is not limited to, a continuous wave (CW) source. The signal source 132 produces a signal that is applied to the modulator 134. The modulator further receives the chaotic reference signal C(t) and imparts to the signal from the signal source 132 a modulation that is proportional to the chaotic reference signal C(t). A modulated output signal produced by the modulator 134 is the chaotic stimulus signal S(t) of the chaotic excitation source 130 illustrated in FIG. 2B.

In various embodiments, the modulator 134 may be essentially any analog modulator, digital modulator, or combination thereof that can modulate the signal from the signal source 132 according to the chaotic reference signal C(t). For example, the modulator 134 may amplitude modulate the signal from the signal source 132 such that the chaotic stimulus signal S(t) has an amplitude modulation that is proportional to the chaotic reference signal C(t). In another example, the modulator 134 may be a phase modulator that applies to the signal from the signal source 132 a phase modulation proportional to the chaotic reference signal C(t). For example, the phase modulation may be of essentially any form including, but not limited to, analog phase modulation, binary phase-shift keying (BPSK), quadrature phase shift keying (QPSK), and m-ary phase shift keying (e.g., 8-PSK, 16-PSK, etc.). In yet other examples, the modulator 134 may be a general modulator the produces complex modulations including, but not limited to, various combinations of AM and PM modulations that are proportional to the chaotic reference signal C(t).

FIG. 2C illustrates a block diagram of a chaotic excitation source 130 according to another embodiment of the present invention. As illustrated in FIG. 2C, the chaotic excitation source 130 comprises the signal source 132, as described above, and a mixer 136. In some embodiments, the mixer 136 is essentially a signal multiplier that multiplies together a pair of signals to produce a product thereof. The mixer 136 employs the chaotic reference signal C(t) as a chaotic carrier. The signal from the signal source 132 is ‘added’ by the action of the mixer 136 to the chaotic carrier as a sideband to produce the chaotic excitation signal S(t). In various other embodiments (not illustrated), the chaotic excitation source 130 may be a combination of one or more of the excitation sources 130 illustrated in FIGS. 2A-2C.

Referring again to FIG. 1C, in some embodiments, the chaotic excitation source 130 may further comprise an output (e.g., an output port) that is connected to an input (e.g., an input port) of the chaotic reference source 110. A signal produced by the excitation source 130 at the output may be the input signal u(t) from the signal source 132, for example. In such embodiments, the chaotic reference source110 may employ the input signal u(t) in generating the chaotic reference signal C(t). For example, the chaotic reference source 110 may employ the input signal u(t), as described by the modulator equations (2) discussed above.

In particular, in an example of employing equations (2)-(4), let the vector c=0, so that the scalar variable y=ƒ(x,u) and the inverse system simply comprises an inverse function ƒ¹(x,u) with respect to the input signal u(t). The exemplary chaotic stimulus signal S(t) created by the excitation source 130 and applied to an input of the DUT 102 may be as given by a last equation of the modulator equations (2), namely S(t)=(x₁(t)+DC)·u(t). Similarly, the chaotic response signal R(t) equals (x₁(t)+DC)²·u(t). For the example, the inverse system (i.e., equations (3)) may comprise an inverse of a quadratic function where ƒ(•) is a quadratic function and an inverse of a cubic function where ƒ(•) is a cubic function. In either case the inverse function is generally known analytically.

In general, the objective is to create two essentially identical systems which are both chaotic and which will synchronize with one another. As exemplified by equations (2)-(4), an ‘observer’ function (i.e., the difference equations (4)) may be created having a property that a difference between the two chaotic systems is linear. Since the difference is linear, conventional linear control theory may be employed to synchronize the systems. The form of the equations (2)-(4) above will yield synchronization, provided that the linear difference of the two systems goes to a fixed point. Creating an observer function of the form of equation (4) is but one example of how the linear difference going to a fixed point may be provided. While exemplified by the difference equation (4) above, the skilled artisan will readily recognize that there are many other possible ways to provide that the linear difference goes to a fixed point.

In some embodiments (not illustrated), the chaotic reference source 110 may further comprise a delay element. The delay element may be located in one or both of a pair of output paths from of the chaotic reference source 110 to a respective one of the chaotic lock-in amplifier 120 and the chaotic excitation source 130, for example. The delay element introduces a time delay in the chaotic reference signal C(t) passing therethrough. For example, the delay element may be employed to introduce a time delay δt in the chaotic reference signal C(t) that is applied to the reference port of a chaotic lock-in amplifier 120. The introduced time delay δt may correspond to a time delay associated with the DUT 102, for example. By introducing the time delay δt, a time-delayed chaotic reference signal C(t-δt) is produced that better corresponds with the chaotic component of the chaotic response signal R(t).

In general, a specific realization of the chaotic stimulus signal S(t) beyond having a component proportional to the chaotic reference signal C(t) is dictated by the DUT 102 and the type of measurements being performed. As such, a specific realization of the chaotic excitation source 130 is essentially a function of the DUT 102 and measurement(s) being performed. Likewise, a nature of the response produced by the DUT 102 is largely a function of the DUT 102 and the measurements being performed thereon. Hence, a form of the receiver 140, whether or not one is included, as well as the specific realization of the chaotic lock-in amplifier 120 are largely DUT 102 dependent and measurement dependent. Given the discussion herein and examples provided below, one skilled in the art may readily select an appropriate excitation source 130 for generating the chaotic stimulus signal S(t) without undue experimentation.

Consider, for example and not by way of limitation, the measurement system 100 wherein a composition of a sample under test (e.g., biomolecules or chemicals in solution) 102 is determined from a fluorescence spectrum produced by exciting the sample under test using a laser. In the exemplary embodiment, the chaotic excitation source 130 of the measurement system 100 comprises a laser that produces an optical chaotic stimulation signal S(t) by modulating an optical signal of the laser using the chaotic reference signal C(t). For example, the laser may provide a modulation input that is used to directly modulate an optical signal produced using the chaotic reference signal C(t). In such embodiments, the chaotic excitation source 130 comprises the laser with the modulation input. In another exemplary embodiment, the optical chaotic stimulation signal S(t) is created by passing the laser-produced optical signal through an electro-optic modulator that is driven by the chaotic reference signal C(t). In such an embodiment, the chaotic excitation source 130 comprises the laser and the electro-optic modulator.

In this example, the optical chaotic stimulation signal S(t) is applied to the sample under test (SUT) 102. The SUT 102 having been stimulated with the optical chaotic stimulation signal S(t) produces a fluorescence response or output signal r(t). A receiver 140 comprising a photodetector receives and transforms the fluorescence output signal r(t) into the chaotic response signal R(t) comprising an analog voltage, for example. The chaotic response signal R(t) is applied to the input port of the chaotic lock-in amplifier 120 and mixed or multiplied with the chaotic reference signal C(t), also an analog voltage. A lowpass filter of the chaotic lock-in amplifier 120 filters and essentially removes any high frequency components that result from the multiplication to produce an output signal ũ(t) that is proportional to a fluorescence response of the sample 102 without the chaotic modulation. Noise, including, but not limited to, background optical signals and detector shot noise, for example and not by way of limitation, associated with one or both of the fluorescence output signal r(t) and the chaotic response signal R(t) is also reduced by the action of the chaotic lock-in amplifier 120. A spectrum of the processed chaotic response signal R(t) represented by the output signal ũ(t) of the chaotic lock-in amplifier 120 is then generated by a spectrum analyzer or using Fourier analysis, for example.

In another example, the DUT 102 is an active device 102 including, but not limited to, an amplifier, and the measurement system 100 is a broadband test system. In such an exemplary measurement system 100, a response of the DUT 102 may be compared to a set of specifications for the DUT 102 to determine whether or not the DUT 102 is operating within normal parameters. The chaotic excitation source 130 may comprise an arbitrary waveform generator with a control input coupled to the output of the chaotic reference source 110, for example. The control input modulates or varies an output signal of the arbitrary waveform generator 130 such that a chaotic stimulation signal S(t) compatible with the input of the exemplary active device 102. An output chaotic response signal R(t) produced by the exemplary active device 102 is applied to the input port of the chaotic lock-in amplifier 120. No receiver 140 is used in the present example since the chaotic response signal R(t) produced by the active device 102 is compatible with the chaotic lock-in amplifier 120.

In yet another example, the DUT 102 is a broadband microwave component and the measurement system 100 is an IF spectrum analyzer. In such an exemplary measurement system 100, the chaotic excitation source 130 may be a two stage microwave upconverter, for example and not by way of limitation. A first upconversion stage of the microwave upconverter 130 employs the chaotic reference signal C(t) to create an IF signal. A second upconversion stage of the microwave upconverter 130 employs a conventional microwave oscillator to produce the chaotic excitation signal S(t) having a center frequency near a center frequency of an input band of the exemplary broadband microwave component 102. A microwave receiver 140 downconverts an output signal r(t) received from the exemplary component 102 to generate the chaotic response signal R(t) at a frequency compatible with the chaotic lock-in amplifier 120.

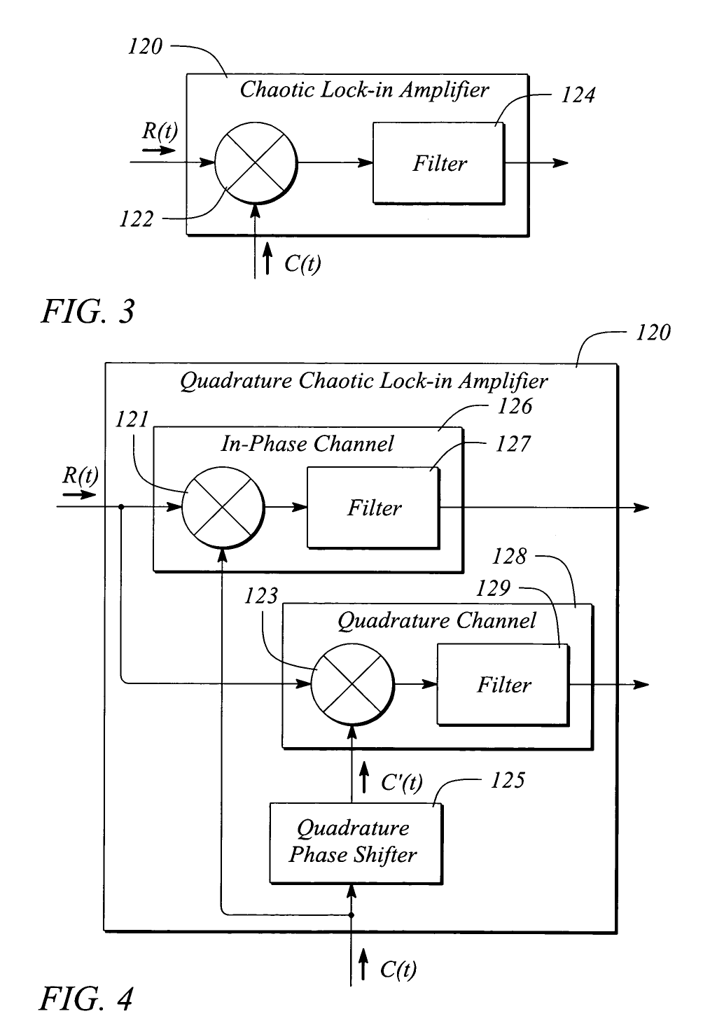

FIG. 3 illustrates a block diagram of a chaotic lock-in amplifier 120 employed in the measurement system 100 illustrated in FIGS. 1A-1B according to an embodiment of the present invention. As illustrated in FIG. 3, the chaotic lock-in amplifier 120 comprises a multiplier 122, an output of which is connected to a lowpass filter 124. The multiplier 122 has a first input connect to the chaotic lock-in amplifier 120 input port and a second input connected to the chaotic lock-in amplifier 120 reference port. An output of the lowpass filter 124 is connected to the chaotic lock-in amplifier 120 output port. Depending on an implementation of the multiplier 122 (e.g., real or complex) and an implementation of the lowpass filter 124, the chaotic lock-in amplifier 120 illustrated in FIG. 3 may handle one or both of real response signals R(t) and complex response signals R(t).

FIG. 4 illustrates a block diagram of a quadrature chaotic lock-in amplifier 120 according to another embodiment of the measurement system 100 illustrated in FIGS. 1A-1B. As illustrated in FIG. 4, the quadrature chaotic lock-in amplifier 120 comprises a first real multiplier 121 and a second real multiplier 123. As used herein, a ‘real multiplier’ accepts a pair of real-valued signals and produces a real-valued product thereof. For example, the first multiplier 121 and second multiplier 123 may comprise analog mixers.

An input port of the quadrature chaotic lock-in amplifier 120 is connected to a first input of the first multiplier 121. The input port is further connected to a first input of the second multiplier 123. The first input of the first multiplier 121 is sometimes referred to as an in-phase (I) input port while the first input of the second multiplier 123 is sometimes referred to as the quadrature (Q) input port. In some embodiments, the I and Q input ports may be connected together to form a single I/Q input port as illustrated in FIG. 4. Alternatively, the I input port and the Q input port may be two separate or distinct ports of the quadratic chaotic lock-in amplifier 120 (not illustrated). A reference port of the quadrature chaotic lock-in amplifier 120 is connected to a second input of the first multiplier 121. The reference port receives the chaotic reference signal C(t).

The quadrature chaotic lock-in amplifier 120 further comprises a quadrature phase shifter 125. The quadrature phase shifter 125 is connected between the reference port of the quadrature chaotic lock-in amplifier 120 and a second input of the second multiplier 123. The quadrature phase shifter 125 introduces a 90-degree phase shift into an instantaneous phase of a signal applied to and passing through the phase shifter 125.

In some embodiments, the quadrature phase shifter 125 is a filter that implements a Hilbert Transform s_{H}(t) of an applied signal s(t). The Hilbert Transform is given by

$${s}_{H} ( t ) = {π}^{- 1} P . V . {\int }_{- ∞}^{+ ∞} \frac{s ( t )}{t - τ} ⅆ τ \qquad ( 5 )$$

where ‘P.V.’ refers to an integral that is taken in the sense of a Cauchy principle value. The applied signal s(t) is a real signal from which a complex ‘analytic’ signal; (t) may be constructed using
ζ(t)=s(t)+js_{H}(t)=A(t)e^{jφ(t)} (6)
where ‘j’ equals \sqrt{−1} and denotes an imaginary portion of the complex analytic signal ζ(t). As indicated in equation (3), the complex analytic signal ζ(t) may also be equivalently represented in terms of an instantaneous amplitude A(t) and an instantaneous phase φ(t). For example, the quadrature phase shifter 125 may comprise an electronic filter having an amplitude response that is essentially unity and a phase response that is essentially a constant lag of π/2 at all frequencies. In another example, the quadrature phase shifter 125 may be implemented using digital signal processing. For example, Matlab® provides a function ‘hilbert(x)’ that essentially implements the Hilbert Transform in a form suitable for implementing the quadrature phase shifter 125 in a digital signal processing form. Matlab® is a numerical computational environment that includes signal processing functions, published by The Mathworks, Inc., Natack, Mass. One skilled in the art is familiar with the Hilbert Transform and its implementation and may readily identify other realizations of the quadrature phase shifter 125 beyond those listed above. All such realizations are within the scope of the present invention.

The quadrature lock-in amplifier 120 further comprises a first lowpass filter 127 and a second lowpass filter 129. The first lowpass filter 127 is connected between an output of the first multiplier 121 and an in-phase (I) output port of the quadrature lock-in amplifier 120. The second lowpass filter 129 is connected between an output of the second multiplier 123 and a quadrature (Q) output port of the quadrature lock-in amplifier 120. The lowpass filters 127, 129 essentially remove any unwanted frequency components produced by the multipliers 121, 123. In effect, the quadrature chaotic lock-in amplifier 120 essentially comprises an in-phase channel 126, a quadrature channel 128 and the quadrature phase shifter 125. The in-phase channel 126 comprises the first multiplier 121 and the first filter 127; and the quadrature channel 128 comprises the second multiplier 123 and the second filter 129.

In some embodiments, the quadrature lock-in amplifier 120 further comprises a chaotic reference source (not illustrated) connected to the reference port. In such embodiments, the chaotic reference source of the quadrature lock-in amplifier 120 may be synchronized to the chaotic reference source 110 of the measurement system 100. In some embodiments (not illustrated), the quadrature phase shifter 125 may be located between the quadrature input port and the first input of the second multiplier 123 instead of between the reference port and the reference input of the second multiplier 123. In yet other embodiments, the quadrature phase shifter 125 may be located between the quadrature input port and the first input of the second multiplier 123 as well as between the reference port and the reference input of the second multiplier 123.

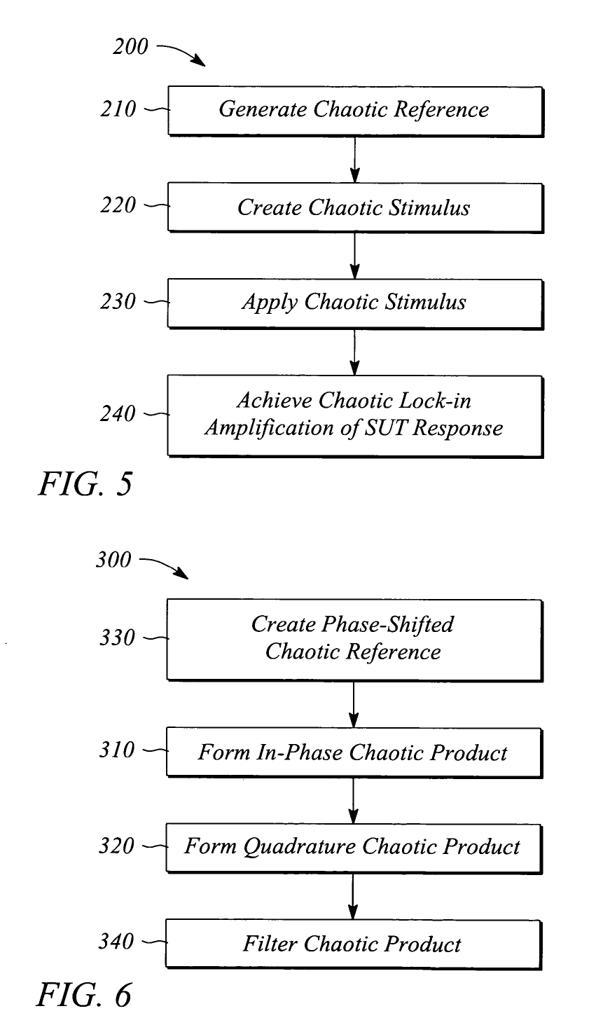

FIG. 5 illustrates a flow chart of a method 200 of measuring a response to a stimulation using chaotic lock-in amplification according to an embodiment of the present invention. In various embodiments of the method 200, a stimulation response of one or more of a sample under test, a device under test, a system under test is measured 200. For simplicity herein and not by way of limitation, the term ‘sample under test’ or ‘SUT’ is employed to mean one or more of the sample under test, the device under test, and the system under test to which a stimulation is applied and for which a response is measured unless indicated otherwise. In some embodiments, the method 200 of measuring generally improves a signal to noise ratio of the response to the stimulation, thereby facilitating extraction of a small response signal buried in relatively larger noise.

The method 200 of measuring comprises generating 210 a chaotic reference signal C(t). The chaotic reference signal C(t) is essentially any signal having or exhibiting chaotic oscillation, as described above. For example, the chaotic reference signal C(t) may be generated by a chaotic system such as, but not limited to, a Lorenz system.

The method 200 of measuring further comprises creating 220 a chaotic stimulus signal S(t). When created 220, the chaotic stimulus signal S(t) comprises at least one signal component that is proportional to the chaotic reference signal C(t). The chaotic stimulus signal S(t) is a stimulus signal of a form that is compatible with stimulating a response from the SUT. In some embodiments, the chaotic stimulus signal S(t) is created by modulating a stimulus signal with the chaotic referenced signal C(t). For example, creating 220 may comprise employing the chaotic reference signal C(t) to one or both of amplitude modulate and phase modulate the stimulus signal.

The method 200 of measuring further comprises applying 230 the chaotic stimulation signal S(t) to an input of the SUT. Applying 230 causes the SUT to produce a chaotic response signal R(t). For example, an optical chaotic stimulation signal S(t) may be applied to a sample under test by illuminating the sample with the optical chaotic stimulation signal S(t). The illuminated sample under test fluoresces as a result of the illumination by the applied optical chaotic stimulation signal S(t). The stimulated fluorescence of the sample under test is received by a photodetector and converted into an electrical signal representing the chaotic response signal R(t). In another example, an electrical chaotic stimulation signal S(t) is applied to an input of a system under test that, in turn, produces an electrical chaotic response signal R(t).

In general, the chaotic response signal R(t) is accompanied by noise. For example, referring back to the optically stimulated sample under test, the noise present in the chaotic response signal R(t) may include, but is not limited to, background optical signals and other ambient noise as well as shot noise or similar detector noise introduced by the photodetector. A ratio of a power of the noise present in the response signal R(t) to a power of a desired component of the response signal R(t) is referred to as a signal to noise ratio. The skilled artisan is familiar with other essentially similar definitions of signal to noise ratio that may be employed in place of that presented above. All such definitions of signal to noise ratio known in the art are within the scope of the present invention.

The method 200 of measuring further comprises achieving 240 chaotic lock-in amplification of the chaotic response signal R(t) generated by the SUT. Achieving 240 chaotic lock-in amplification employs the chaotic reference signal C(t) to lock-in to the chaotic signal component(s) of the chaotic response signal R(t). The lock-in essentially removes the chaotic signal component(s) of the chaotic response signal R(t). In addition, concomitant with the removal is a general increase in the signal to noise ratio.

In some embodiments, achieving 240 chaotic lock-in amplification comprises multiplying together or forming a product of the chaotic response signal R(t) and the chaotic reference signal C(t). In some embodiments, chaotic lock-in amplification 240 further comprises filtering the formed product to remove undesired frequency components from the product. For example, a lowpass filter may be employed to remove high frequency components of the formed product.

FIG. 6 illustrates a flow chart of a method 300 of quadrature chaotic lock-in amplification according to an embodiment of the present invention. The method 300 of quadrature chaotic lock-in amplification comprises forming 310 an in-phase chaotic product. Forming 310 the in-phase chaotic product comprises multiplying together a chaotic input signal and a chaotic reference signal C(t) to form an in-phase product. The chaotic input signal comprises at least one chaotic component proportional to or synchronized with the chaotic reference signal C(t). For example, the chaotic input signal may be one or both of amplitude modulated and phase modulated by the chaotic reference signal C(t). In some embodiments, the chaotic input signal is a chaotic response signal R(t) produced by an SUT, as described above with respect to the method of measuring 200.

The method 300 of quadrature chaotic lock-in amplification further comprises forming 320 a quadrature chaotic product. Forming 320 a quadrature chaotic product comprises multiplying together the chaotic input signal and a phase-shifted chaotic reference signal C′(t) to form a quadrature product. The phase-shifted chaotic reference signal C′(t) represents the chaotic reference signal C(t) having a nominal 90-degree instantaneous phase shift applied thereto.

As illustrated in FIG. 6, in some embodiments, the method 300 further comprises creating 330 the phase-shifted chaotic reference signal C′(t) from the chaotic reference signal C(t) using a Hilbert Transform. For example, the phase-shifted chaotic reference signal C′(t) may be created 330 by passing the chaotic reference signal C(t) through a filter that implements the Hilbert Transform. Generally, the phase-shifted chaotic reference signal C′(t) is created 330 prior to forming 320 a quadrature chaotic product so that the phase-shifted chaotic reference signal C′(t) is available for use to form 320 the quadrature chaotic product.

Also as illustrated in FIG. 6, in some embodiments, the method 300 further comprises filtering 340 the in-phase chaotic product and the quadrature chaotic product. In such embodiments, a first lowpass filter may be employed to filter 340 the in-phase product while a second lowpass filter may be used to filter the quadrature product. For example and not by way of limitation, the quadrature chaotic lock-in amplifier 120, which was described above and illustrated in FIG. 4, comprises multipliers 121, 123 and filters 127, 129 that form 310, 320 and filter 340 the in-phase chaotic product and the quadrature chaotic product in some embodiments, according to the method 300 of quadrature chaotic lock-in amplification.

Thus, there have been described embodiments of a stimulation-response measurement system employing chaotic lock-in amplification, a quadrature chaotic lock-in amplifier, and respective methods thereof. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A stimulus-response measurement system comprising:
a chaotic reference source that produces a chaotic reference signal;
a chaotic excitation source that produces a chaotic excitation signal from the chaotic reference signal, and
a chaotic lock-in amplifier,
wherein the chaotic lock-in amplifier employs the chaotic reference signal to lock-in a chaotic component of a chaotic response signal produced by one or more of a device under test, a sample under test and a system under test being stimulated by the chaotic excitation signal, such that the lock-in of the chaotic component facilitates detection of the chaotic response signal.

2. The stimulus-response measurement system of claim 1, wherein the chaotic lock-in amplifier comprises a multiplier that multiplies the chaotic reference signal and the chaotic response signal, the multiplier producing an output signal having an improved signal to noise ratio relative to a signal to noise ratio of the chaotic response signal.

3. The stimulus-response measurement system of claim 2, wherein the improved signal to noise ratio facilitates measuring a characteristic of the respective one or more device under test, sample under test and system under test.

4. The stimulus-response system of claim 1, wherein the chaotic lock-in amplifier comprises an inverse system.

5. The stimulus-response measurement system of claim 1, wherein the chaotic component comprises one or more of a chaotic modulation and a chaotic carrier, the chaotic component being proportional to the chaotic reference signal, and wherein the lock-in essentially removes the chaotic component from the chaotic response signal to produce an output signal.

6. The stimulus-response measurement system of claim 5, wherein the one or both of the chaotic modulation and the chaotic carrier are characteristics of the chaotic excitation signal.

7. The stimulus-response measurement system of claim 1, wherein the chaotic excitation source comprises a signal source and a modulator, the modulator receiving the chaotic reference signal and producing a modulation of a signal from the signal source that is proportional to the chaotic reference signal.

8. The stimulus-response measurement system of claim 7, wherein the modulation comprises an amplitude modulation.

9. The stimulus-response measurement system of claim 7, wherein the modulator comprises one or more of an analog modulator and a digital modulator.

10. The stimulus-response measurement system of claim 1, further comprising a receiver that receives the chaotic response signal from the respective one or more of device under test, sample under test and system under test, the receiver transforming the chaotic response signal into a form compatible with the chaotic lock-in amplifier.

11. The stimulus-response measurement system of claim 10, wherein the chaotic response signal is an optical signal, the receiver comprising an optical detector that transforms the optical signal into an electrical signal, the electrical signal being compatible with the chaotic lock-in amplifier.

12. The stimulus-response measurement system of claim 10, wherein the chaotic response signal is a signal having a center frequency, the receiver comprising a frequency converter that transforms the center frequency of the signal to another center frequency compatible with the chaotic lock-in amplifier.

13. The stimulus-response measurement system of claim 1, wherein the chaotic lock-in amplifier further comprises a lowpass filter that removes high frequency components from an internal signal of the lock-in amplifier to produce an output signal.

14. The stimulus-response measurement system of claim 1, wherein the chaotic lock-in amplifier comprises a quadrature chaotic lock-in amplifier having an in-phase channel, a quadrature channel, and a quadrature phase shifter, the quadrature channel employing a phase-shifted chaotic reference signal produced from the quadrature phase shifter using the chaotic reference signal.

15. The stimulus-response measurement system of claim 12, wherein the phase-shifter comprises a filter implementing a Hilbert Transform.

16. A chaotic lock-in amplifier comprising:
an inverse system that receives a chaotic input signal at a first input port; and
a chaotic reference source that generates a chaotic reference signal, the chaotic reference signal being applied to a second input port of the inverse system,
wherein the inverse system combines together the chaotic input signal and the chaotic reference signal to produce a signal at an output port of the inverse system, the produced signal being the chaotic input signal with a chaotic component removed.

17. The chaotic lock-in amplifier of claim 16, further comprising a lowpass filter that filters the produced signal to reduce a level of high frequency components in the produced signal.

18. A quadrature chaotic lock-in amplifier comprising:
an in-phase channel comprising a first multiplier having a first input and a second input, the first input being connected to an in-phase input port of the quadrature chaotic lock-in amplifier, the second input being connected to a reference port of the quadrature chaotic lock-in amplifier;
a quadrature channel comprising a second multiplier having a first input and a second input, the first input being connected to a quadrature input port of the quadrature chaotic lock-in amplifier; and
a quadrature phase shifter having an input connected to the reference port and an output connected to the second input of the second multiplier, the quadrature phase shifter phase-shifting a chaotic reference signal applied to the reference port to produce a quadrature chaotic reference signal.

19. The quadrature chaotic lock-in amplifier of claim 18, wherein a chaotic input signal introduced to the in-phase input port is multiplied by the chaotic reference signal in the first multiplier to produce an in-phase product, and wherein the chaotic input signal further introduced to the quadrature input port is multiplied by the quadrature chaotic reference signal in the second multiplier to produce a quadrature product.

20. The quadrature chaotic lock-in amplifier of claim 19, further comprising:
a first lowpass filter between an output of the first multiplier and an in-phase output port of the quadrature lock-in amplifier; and
a second lowpass filter between an output of the second multiplier and a quadrature output port of the quadrature lock-in amplifier,
wherein the first lowpass filter and the second lowpass filter respectively filter the in-phase product and the quadrature product.

21. The quadrature chaotic lock-in amplifier of claim 19 used in a stimulus-response measurement system, the system further comprising:
a chaotic reference source that generates the chaotic reference signal; and
a chaotic excitation source that generates a chaotic excitation signal,
wherein the chaotic excitation signal applied to one or more of a device under test, a sample under test and a system under test produces the chaotic input signal that is introduced to the input ports of the quadrature chaotic lock-in amplifier.

22. A method of measuring a response to a stimulation, the method comprising:
generating a chaotic reference signal;
creating a chaotic stimulus signal having at least one signal component that is proportional to the chaotic reference signal;
applying the chaotic stimulus signal to an input of one or more of a sample under test, a device under test, and a system under test to produce a chaotic response signal; and
achieving chaotic lock-in amplification of the chaotic response signal using the chaotic reference signal,
wherein the chaotic lock-in amplification preferentially removes a chaotic component from the chaotic response signal to yield a measurement of a response to the stimulation from respective one or more of the sample under test, the device under test, and the system under test.

23. The method of measuring of claim 22, wherein achieving chaotic lock-in amplification comprises:
multiplying together the chaotic response signal and the chaotic reference signal to form a product.

24. The method of measuring of claim 23, wherein achieving chaotic lock-in amplification further comprises filtering the formed product.

25. The method of measuring of claim 24, wherein filtering comprising passing the formed product through a lowpass filter to remove high frequency components of the product.

26. The method of measuring of claim 22, wherein achieving chaotic lock-in amplification comprises:
applying an inverse system to a combination of the chaotic response signal and the chaotic reference signal to remove a chaotic component from the chaotic response signal.

27. The method of measuring of claim 22, wherein creating a chaotic stimulus signal comprises employing the chaotic reference signal to one or both of amplitude modulate and phase modulate a stimulus signal that is compatible with the respective one or more of sample under test, device under test, and system under test.

28. A method of quadrature chaotic lock-in amplification of a chaotic input signal, the method comprising:
multiplying together the chaotic input signal and a chaotic reference signal to form an in-phase chaotic product; and
multiplying together the chaotic input signal and a phase-shifted chaotic reference signal to form a quadrature chaotic product,
wherein the phase-shifted chaotic reference signal is the chaotic reference signal having an phase shift of approximately 90-degrees.

29. The method of quadrature chaotic lock-in amplification of claim 28, wherein the chaotic input signal comprises at least one chaotic component that is one or both of proportional to and synchronized with the chaotic reference signal.

30. The method of quadrature chaotic lock-in amplification of claim 28, further comprising creating the phase-shifted chaotic reference signal using a Hilbert Transform prior to forming the quadrature chaotic product.

31. The method of quadrature chaotic lock-in amplification of claim 28, further comprising filtering one or both of the in-phase product and the quadrature product using a lowpass filter to remove high frequency components of the respective products.
